(19) United States
(12) Patent Application Publication
(10) Pub. No.: US 2007/0057252 A1
(43) Pub. Date: Mar. 15, 2007

(54) Organic thin film transistor with contact hole and method for fabricating the same

(75) Inventors: Cheng-Chung Hsieh, Chutung Township (TW); Tarng-Shiang Hu, Hsinchu (TW); Jia-Chong Ho, Yingge Township (TW); Ming-Chun Hsiao, Jhudong Township (TW)

Correspondence Address: MICHAEL W. TAYLOR, P.O. BOX 3791, ORLANDO, FL, 32802-3791, US

(73) Assignee: Industrial Technology Research Institute, Hsinchu (TW)

(21) Appl. No.: 11/367,734

(22) Filed: Mar. 3, 2006

(30) Foreign Application Priority Data
Sep. 12, 2005 (TW) 94131383

(51) Int. Cl. H01L 29/08; H01L 29/04

(52) U.S. Cl. 257/40; 257/E29.273; 257/72

(57) ABSTRACT

The present invention provides a method for fabricating an organic thin film transistor (OTFT) device where a vertical contact hole is produced in the insulating layer and the passivation layer thereof, so that the respective devices located below and above the OTFT would be electrically connected with each other. The provided OTFT device includes a substrate, a gate layer located on the substrate, an insulating layer located on the gate layer, an electrode layer located on the insulating layer and having a source region and a drain region, an organic semiconductor layer located between the source region and the drain region, a passivation layer patterned and located on the source region, the drain region and the organic semiconductor layer, and a contact hole passing through the passivation layer to one of the source region and the drain region.

### FIELD OF THE INVENTION

The present invention relates to a transistor device and the fabrication method therefor, and more particularly, to an organic thin film transistor device and a corresponding method for fabricating the same.

### BACKGROUND OF THE INVENTION

The organic thin film transistor (OTFT) is now broadly applied for the flexible substrate, the display and the portable electronic device such as electronic tags and intelligent cards, owing to the advantages of simple fabrication and low cost thereof.

Recently, the combination of OTFT and soft electronic device is typically developed in the electronics relevant industry. In particular, it is believed that the improvement of organic transistor plays an important role in the application of OTFT for the flexible display, and more and more efforts are made therefor.

In comparison with the inorganic semiconductor transistor, the OTFT is provided with an organic semiconductor layer, and thus possesses a relatively frail structure. Accordingly, it always needs to provide a passivation layer on the organic semiconductor layer, so as to sufficiently protect such organic device from being damaged. Moreover, the organic semiconductor layer in the OTFT is also easily damaged while being etched, and hence it still fails to produce the contact hole on the OTFT via local etching now, which largely limits the application of OTFT.

For overcoming the mentioned drawbacks, a novel OTFT device as well as the fabrication method therefor is provided in the present invention. Through the present invention, the OTFT device is provided with a contact hole structure in a simple and economic way, and the organic semiconductor layer in the provided OTFT would be well protected therein. In addition, the provided method is compatible with the existing process, which owns a great potential in application.

### SUMMARY OF THE INVENTION

The present invention provides an organic thin film transistor (OTFT) device with a contact hole therein in a simple way, where the organic semiconductor layer in the OTFT device would be well protected from being damaged while the contact hole is produced.

The present invention further provides a method for fabricating an OTFT device where a vertical contact hole is produced in the insulating layer and the passivation layer thereof, so that the respective devices located below and above the OTFT would be electrically connected with each other.

In accordance with a first aspect of the present invention, an OTFT device is provided. The provide OTFT device includes a substrate, a gate layer located on the substrate, an insulating layer located on the gate layer, an electrode layer located on the insulating layer and having a source region and a drain region, an organic semiconductor layer located between the source region and the drain region, a passivation layer patterned and located on the source region, the drain region and the organic semiconductor layer, and a contact hole passing through the passivation layer to one of the source region and the drain region.

In accordance with a second aspect of the present invention, an OTFT device with a contact hole structure is provided in the present invention. The provided OTFT device includes a substrate, a gate layer located on the substrate, an insulating layer located on the gate layer, a source/drain layer located on the insulating layer and having a channel therein, an organic semiconductor layer located on the channel in the source/drain layer, a passivation layer located on the source/drain layer and the semiconductor layer, and a mask located on the passivation layer.

According to the mentioned aspect, the organic semiconductor layer is provided with a contact hole passing through the mask and the passivation layer to the source/drain layer.

In accordance with a third aspect of the present invention, an OTFT device with a contact hole structure is provided, which includes a substrate, a gate layer located on the substrate, an insulating layer located on the gate layer, an organic semiconductor layer located on the insulating layer, a source/drain layer located on the organic semiconductor, a passivation layer located on the source/drain layer and the semiconductor layer, and a mask located on the passivation layer.

According to the mentioned aspect, the organic semiconductor layer is provided with a contact hole passing through the mask and the passivation layer to the source/drain layer.

Preferably, the passivation layer is made of an organic material.

Preferably, the organic material is parylene.

Preferably, the contact hole is produced by means of etching.

Preferably, the contact hole is produced by performing a plasma etching.

Preferably, the mask is one selected from a group consisting of a metal layer and an oxide layer.

Preferably, the metal layer is made of aluminum.

Preferably, the oxide layer is an indium tin oxide layer.

In accordance with a fourth aspect of the present invention, a method for fabricating an organic thin film device with a contact hole structure is provided. The method includes steps of (a) providing a substrate; (b) forming a gate layer on the substrate; (c) forming an insulating layer on the gate layer; (d) forming an electrode layer on the insulating layer; (e) providing an organic semiconductor layer between the electrode layer and the insulating layer; (f) forming a passivation layer on the electrode layer, the insulating layer and the organic semiconductor layer; (g) forming a mask layer on the passivation layer; and (h) producing a contact hole passing through the mask layer and the passivation layer to the electrode layer thereby.

In accordance with a fifth aspect of the present invention, a method for fabricating an organic thin film device with a contact hole structure is provided. The method includes steps of: (a) providing a substrate; (b) forming a gate layer on the substrate; (c) forming an insulating layer on the gate layer; (d) forming an organic semiconductor layer on the insulating layer; (e) forming a source/drain layer on the organic semiconductor layer; (f) forming a passivation layer on the source/drain layer and the organic semiconductor layer; (g) forming a mask layer on the passivation layer; and (h) producing a contact hole passing through the mask layer and the passivation layer to the electrode layer thereby.

Preferably, the passivation layer is made of an organic material.

Preferably, the organic material is parylene.

Preferably, the mask layer is one selected from a group consisting of a metal layer and an oxide layer.

Preferably, the metal layer is made of aluminum.

Preferably, the oxide layer is an indium tin oxide layer.

Preferably, the mask layer is patterned.

Preferably, the contact hole is produced by means of etching.

Preferably, the contact hole is produced by performing a plasma etching.

The foregoing and other features and advantages of the present invention will be more clearly understood through the following descriptions with reference to the drawings, wherein:

### BRIEF DESCRIPTION OF THE DRAWINGS

FIGS. 1(a) to 1(e) are diagrams illustrating the steps of the method for fabricating the organic thin film transistor (OTFT) according to a first preferred embodiment of the present invention; and

FIG. 2 is a diagram illustrating the OTFT having a contact hole fabricated by the method according to a second preferred embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

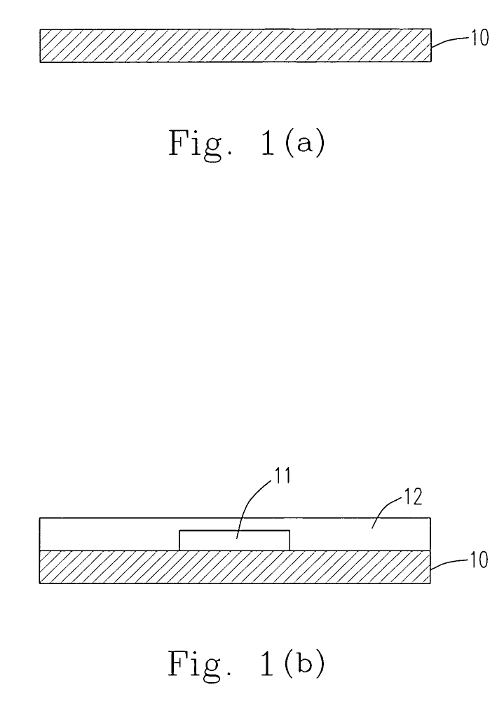

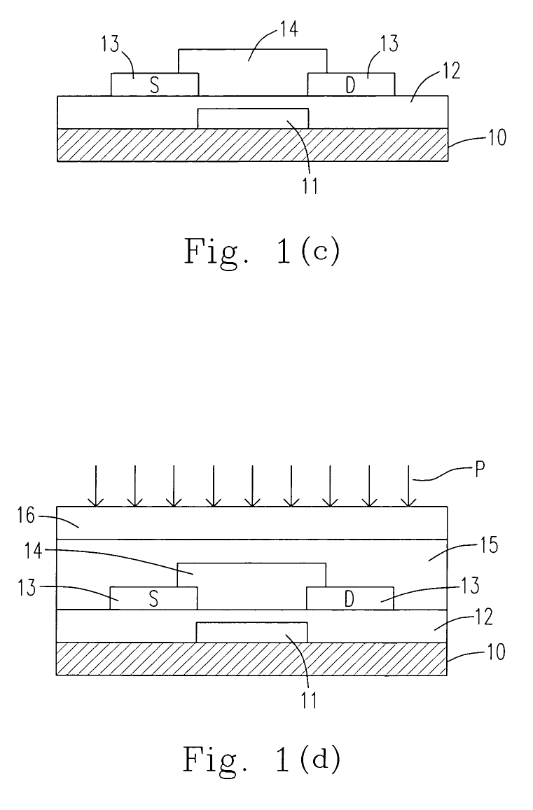

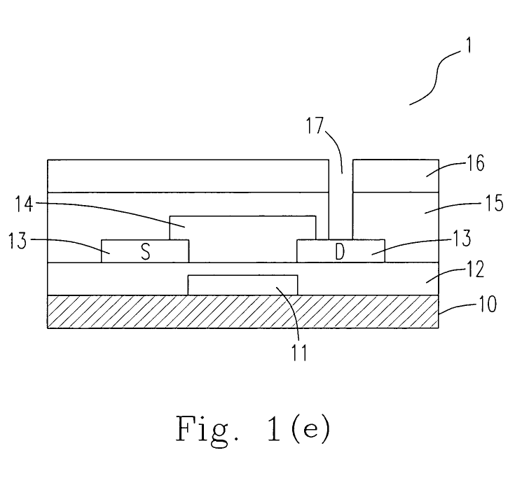

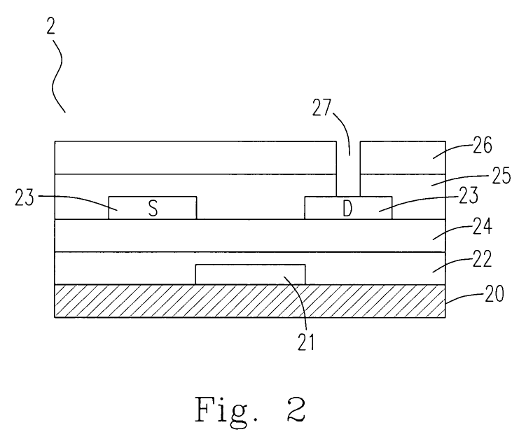

Please refer to FIGS. 1(a) to 1(e), which are diagrams schematically illustrating the steps of the method for fabricating the organic thin film transistor (OTFT) according to a first preferred embodiment of the present invention and the OTFT having a contact hole fabricated thereby. First, a substrate 10 is provided and a gate layer 11 is formed thereon. The substrate 10 is preferably one of a silicon substrate, a glass substrate, a metal substrate and a plastic substrate. The gate layer 11 forms the gate region of the OTFT device, and thereon an insulating layer 12 is formed. The insulating layer 12 is formed on the gate layer 11 by means of deposition or printing, which is made of organic polymer or inorganic material.

Subsequently, an electrode layer 13 including a source regions S and a drain region D is formed on the insulating layer 12. The electrode layer 13 of paste or of ink is composed of organic electrically conductive material, inorganic electrically conductive material or the mixture thereof.

An organic semiconductor layer 14 is produced between the electrode layer 13 and the insulating layer 12. Actually, the organic semiconductor layer 14 is produced via spinning coating or evaporating, which is a semiconducting organic material of small molecule or an organic polymer. Subsequently, a passivation layer 15 is formed and the electrode layer 13, the insulating layer 12 as well as the semiconductor layer 14 are covered therewith. After the passivation layer 15 is provided with a mask 16 thereon, the resulting structure is applied with etching (the direction P as shown in FIG. 1(d)), e.g. the plasma etching, in order that a contact hole 17 is fabricated thereon. Accordingly, the OTFT device 1 with the contact hole 17 of the present invention is thus achieved, where the contact hole 17 penetrates through the mask 16 and the passivation layer 15 and reaches to the electrode layer 13.

In the present invention, the passivation layer 15 is preferably made of an organic material and is more preferably made of parylene. The mask 16 is a patterned metal layer, and is preferably a metal layer of aluminum. Alternatively, the mask 16 is a patterned oxide layer, and is preferably a patterned indium tin oxide (ITO) layer. In a preferred embodiment, for example, the passivation layer 15 is first provided with a shadow mask thereon, and followed by the evaporation so that the aluminum layer is deposited thereon for forming a patterned metal mask. In addition to the plasma etching, other schemes are also adoptable for fabricating the contact hole 17 in the present invention.

In the present invention, the penetrating contact hole is able to be fabricated by means of the patterned mask 16, so as to achieve the OTFT device 1 with a contact hole thereby. The passivation layer 15 of organic material not only protects the organic semiconductor layer 14 as well as the electrode layer 13 from being damaged by the plasma etching, but also prevents the metallic atoms, e.g. the aluminum atoms, in the mask 16 from diffusing thereinto and affecting the electric property thereof. Furthermore, the mask 16 could be left on OTFT device 1 upon and after the contact hole 17 is fabricated, so as to provide a further protection for the device in the plasma etching procedure.

Such method of the present invention is also adoptable for fabricating a top contact OTFT device. Please refer to FIG. 2 illustrating the OTFT device having a contact hole fabricated by the method according to a second preferred embodiment of the present invention, wherein the OTFT device is a top contact OTFT device. Similarly, a substrate 20 is first provided and thereon a gate layer 21 is formed. The substrate 20 is one of a silicon substrate, a glass substrate, a metal substrate and a plastic substrate, and the gate layer 21 forms the gate region of the OTFT device.

Subsequently, an insulating layer 22 of organic polymer or inorganic material is formed on the gate layer 22 via depositing or printing, and thereon an organic semiconductor layer 24 is formed via spinning coating or evaporating, where the organic semiconductor layer 24 is made of an organic semiconducting material of small molecule or an organic polymer.

There is a source (S)/drain (D) layer, i.e. the electrode layer 23, formed on the organic semiconductor layer 24. The electrode layer 23 of paste or of ink is composed of organic electrically conductive material, inorganic electrically conductive material or the mixture thereof.

A passivation layer 25 is then formed above the source (S)/drain (D) layer and the organic semiconductor layer 24 for providing a well protection therefor. The passivation layer 25 is provided with a patterned mask 26 thereon, whereby a contact hole 27 would be fabricated via plasma etching. The contact hole 27 penetrates through the mask 26 as well as the passivation layer 25, and reaches to the source (S)/drain (D) layer. Accordingly, the top contact OTFT device 2 having a contact hole of the present invention is achieved.

Through the method provided in the present invention, it is achievable to fabricate the contact hole on the OTFT device via etching without causing any damage to thereto. By means of the mask according to the present invention, the pattern identical to that of the mask is formed on the layer of organic polymer in the OFTF device upon etching. Furthermore, the mask also serves as the passivation layer for the layer of organic polymer, so as to protect the layer of organic polymer therebelow from being damaged. The present invention not only provides the OTFT device having a contact hole so as to be more applicable for the flexible display, but is also more suitable in patterning the insulating layer and the passivation layer of the OTFT device, which is practically applicable in the technical of the OTFT device application combining the panel of organic light emitting diode (OLED).

Based on the above, the present invention not only has a novelty and a progressiveness, but also has an industry utility.

While the invention has been described in terms of what is presently considered to be the most practical and preferred embodiment, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. An organic thin film transistor device, comprising:
a substrate;
a gate layer located on said substrate;
an insulating layer located on said gate layer;
an electrode layer located on said insulating layer and having a source region and a drain region;
an organic semiconductor layer located between said source region and said drain region;
a passivation layer patterned and located on said source region, said drain region and said organic semiconductor layer; and
a contact hole passing through said passivation layer to one of said source region and said drain region.

2. The organic thin film transistor device according to claim 1, wherein said passivation layer is made of an organic material.

3. The organic thin film transistor device according to claim 9, wherein said organic material is parylene.

4. The organic thin film transistor device according to claim 1, wherein said contact hole is produced by means of etching.

5. The organic thin film transistor device according to claim 4, wherein said contact hole is produced by performing a plasma etching.

6. An organic thin film transistor device with a contact hole, comprising:
a substrate;
a gate layer located on said substrate;
an insulating layer located on said gate layer;
a source/drain layer located on said insulating layer and having a channel therein;
an organic semiconductor layer located on said channel in said source/drain layer;
a passivation layer located on said source/drain layer and said semiconductor layer; and
a mask located on said passivation layer,
wherein said contact hole passing through said mask and said passivation layer to said source/drain layer is defined on said organic semiconductor layer.

7. The organic thin film transistor device according to claim 6, wherein said passivation layer is made of an organic material.

8. The organic thin film transistor device according to claim 7, wherein said organic material is parylene.

9. The organic thin film transistor device according to claim 6, wherein said mask is one selected from a group consisting of a metal layer and an oxide layer.

10. The organic thin film transistor device according to claim 9, wherein said metal layer is made of aluminum.

11. The organic thin film transistor device according to claim 9, wherein said oxide layer is an indium tin oxide layer.

12. The organic thin film transistor device according to claim 6, wherein said mask is a patterned mask.

13. The organic thin film transistor device according to claim 6, wherein said contact hole is produced by means of etching.

14. The organic thin film transistor device according to claim 13, wherein said contact hole is produced by performing a plasma etching.

15. An organic thin film transistor device with a contact hole, comprising:
a substrate;
a gate layer located on said substrate;
an insulating layer located on said gate layer;
an organic semiconductor layer located on said insulating layer;
a source/drain layer located on said organic semiconductor;
a passivation layer located on said source/drain layer and said semiconductor layer; and
a mask located on said passivation layer,
wherein the contact hole passing through said mask and said passivation layer to said source/drain layer is defined on said organic semiconductor layer.

16. A method for fabricating an organic thin film transistor device with a contact hole, comprising steps of:
(a) providing a substrate;
(b) forming a gate layer on said substrate;
(c) forming an insulating layer on said gate layer;
(d) forming an electrode layer on said insulating layer;
(e) providing an organic semiconductor layer between said electrode layer and said insulating layer;
(f) forming a passivation layer on said electrode layer, said insulating layer and said organic semiconductor layer;
(g) forming a mask layer on said passivation layer; and
(h) producing said contact hole passing through said mask layer and said passivation layer to said electrode layer thereby.

17. The method according to claim 16, wherein said passivation layer is made of an organic material.

18. The method according to claim 17, wherein said organic material is parylene.

19. The method according to claim 16, wherein said mask layer is one selected from a group consisting of a metal layer and an oxide layer.

20. The method according to claim 19, wherein said metal layer is made of aluminum.

21. The method according to claim 19, wherein said oxide layer is an indium tin oxide layer.

22. The method according to claim 16, wherein said mask layer is patterned.

23. The method according to claim 16, wherein said contact hole is produced by means of etching.

24. The method according to claim 16, wherein said contact hole is produced by performing a plasma etching.

25. A method for fabricating an organic thin film device with a contact hole, comprising steps of:
(a) providing a substrate;
(b) forming a gate layer on said substrate;
(c) forming an insulating layer on said gate layer;
(d) forming an organic semiconductor layer on said insulating layer;
(e) forming a source/drain layer on said organic semiconductor layer;
(f) forming a passivation layer on said source/drain layer and said organic semiconductor layer;
(g) forming a mask layer on said passivation layer; and
(h) producing said contact hole passing through said mask layer and said passivation layer to said electrode layer thereby.
